(19) United States
(12) Patent Application Publication
(10) Pub. No.: US 2026/0271497 A1
(43) Pub. Date: Sep. 10, 2026

(54) LIGHT-EMITTING ELEMENT, DISPLAY DEVICE, AND METHOD OF MANUFACTURING A LIGHT-EMITTING ELEMENT

(71) Applicant: Sharp Display Technology Corporation, Kameyama City, Mie (JP)

(72) Inventors: HISAYUKI UTSUMI, Kameyama City, Mie (JP); Masayuki KANEHIRO, Kameyama City, Mie (JP)

(21) Appl. No.: 19/133,817

(22) PCT Filed: Dec. 1, 2022
(86) PCT No.: PCT/JP2022/044337

§ 371 Date: May 29, 2025

(51) Int. Cl. H10K 50/115; H10K 59/12; H10K 59/122; H10K 71/12; H10K 85/10; H10K 102/00

(52) U.S. Cl. CPC H10K 50/115; H10K 59/1201; H10K 59/122; H10K 71/12; H10K 85/10; H10K 2102/351

(57) ABSTRACT

A light-emitting element includes: a first electrode; a second electrode; a light-emitting layer positioned between the first electrode and the second electrode; and a first intermediate layer positioned in contact with the light-emitting layer either between the first electrode and the light-emitting layer or between the second electrode and the light-emitting layer or both between the first electrode and the light-emitting layer and between the second electrode and the light-emitting layer, wherein the first intermediate layer contains a novolac-type phenol resin.

### TECHNICAL FIELD

The disclosure relates to light-emitting elements and display devices incorporating the light-emitting elements.

### BACKGROUND ART

In field-injection light-emitting elements, if the layer that is in contact with the light-emitting layer has low planarity, the light-emitting elements have a reduced luminous efficiency. For example, in a light-emitting element, if the layer that is in contact with the light-emitting layer has low planarity, the local contact of this layer and the light-emitting layer could lead to increased local luminescence of the light-emitting layer, which would result in decreased luminous efficiency.

In addition, when the light-emitting layer contains quantum dots as a light-emitting material, if the layer that is an underlayer of the light-emitting layer has a top face with low planarity, the closeness of quantum dots in the light-emitting layer decreases, and the leakage current from the light-emitting element increases, which would cause further decreases in the luminous efficiency of the light-emitting element.

Patent Literature 1 discloses a technology to reduce the leakage current in the light-emitting layer by providing a PMMA resin layer between quantum dots.

### CITATION LIST

### Patent Literature

Patent Literature 1: Published Japanese Translation of PCT Application No. 2020-537338

### SUMMARY

### Technical Problem

In Patent Literature 1, the provision of a PMMA resin layer between quantum dots adds to the thickness of the light-emitting layer, which increases the resistance of the light-emitting element. In addition, it is difficult to improve the planarity of the layer that is in contact with the light-emitting layer by the technology described in Patent Literature 1. Therefore, the technology described in Patent Literature 1 is not capable of efficiently improving the luminous efficiency of the light-emitting element.

### Solution to Problem

The disclosure, in one aspect thereof, is directed to a light-emitting element including: a first electrode; a second electrode; a light-emitting layer positioned between the first electrode and the second electrode and containing a plurality of quantum dots; and a first intermediate layer positioned in contact with the light-emitting layer either between the first electrode and the light-emitting layer or between the second electrode and the light-emitting layer or both between the first electrode and the light-emitting layer and between the second electrode and the light-emitting layer, wherein the first intermediate layer contains a novolac-type phenol resin.

The disclosure, in another aspect thereof, is directed to a method of manufacturing a light-emitting element including: a first electrode; a second electrode; a light-emitting layer positioned between the first electrode and the second electrode; and a first intermediate layer positioned in contact with the light-emitting layer either between the first electrode and the light-emitting layer or between the second electrode and the light-emitting layer or both between the first electrode and the light-emitting layer and between the second electrode and the light-emitting layer, the method including: forming a first coating film by applying a first solution containing a phenolic compound; and forming the first intermediate layer containing a novolac-type phenol resin by condensation polymerization of the phenolic compound in at least a part of the first coating film.

### Advantageous Effects of Disclosure

The disclosure improves the planarity of a first intermediate layer that is in contact with the light-emitting layer, thereby improving the luminous efficiency of the light-emitting element.

### BRIEF DESCRIPTION OF DRAWINGS

FIG. 1 is a schematic cross-sectional side view of a display device in accordance with Embodiment 1.

FIG. 2 is a schematic plan view of the display device in accordance with Embodiment 1.

FIG. 3 is a flow chart representing a method of manufacturing the display device in accordance with Embodiment 1.

FIG. 4 is a schematic cross-sectional manufacturing step diagram for the method of manufacturing the display device in accordance with Embodiment 1.

FIG. 5 is another schematic cross-sectional manufacturing step diagram for the method of manufacturing the display device in accordance with Embodiment 1.

FIG. 6 is another schematic cross-sectional manufacturing step diagram for the method of manufacturing the display device in accordance with Embodiment 1.

FIG. 7 is another schematic cross-sectional manufacturing step diagram for the method of manufacturing the display device in accordance with Embodiment 1.

FIG. 8 is a schematic illustration of a process of how to form a superlattice structure of quantum dots in the method of manufacturing the display device in accordance with Embodiment 1.

FIG. 9 is a schematic cross-sectional side view of a display device in accordance with Embodiment 2.

FIG. 10 is a schematic cross-sectional side view of a display device in accordance with Embodiment 3.

### DESCRIPTION OF EMBODIMENTS

### Embodiment 1

### Display Device: Overview

The following will describe embodiments of the disclosure with reference to drawings. Note that identical or equivalent members are denoted by the same reference numerals throughout the drawings, and their description may not be repeated.

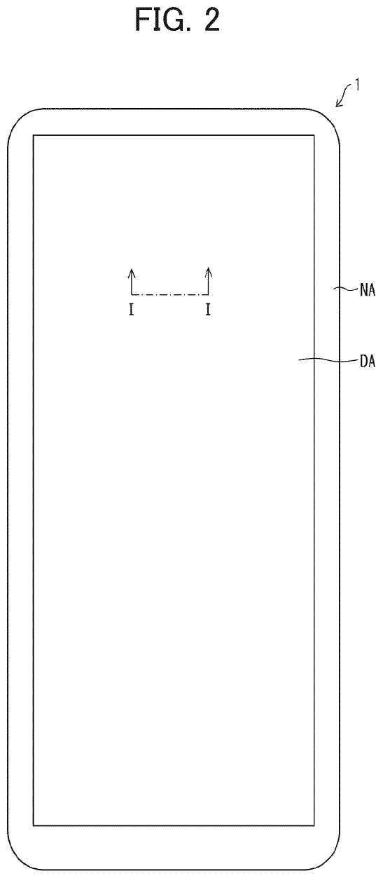

FIG. 2 is a schematic plan view of a display device in accordance with the present embodiment. A display device 1 is, for example, an apparatus that can be used in display devices such as television units and smartphones. The display device 1 includes a display section DA and a frame section NA provided along the outer circumference of the display section DA. The display device 1 produces a display on the display section DA by controlling the emission of light by each of a plurality of light-emitting elements (detailed later) formed in the display section DA. In the frame section NA, there may be provided, for example, a driver for driving each of these plurality of light-emitting elements in the display section DA.

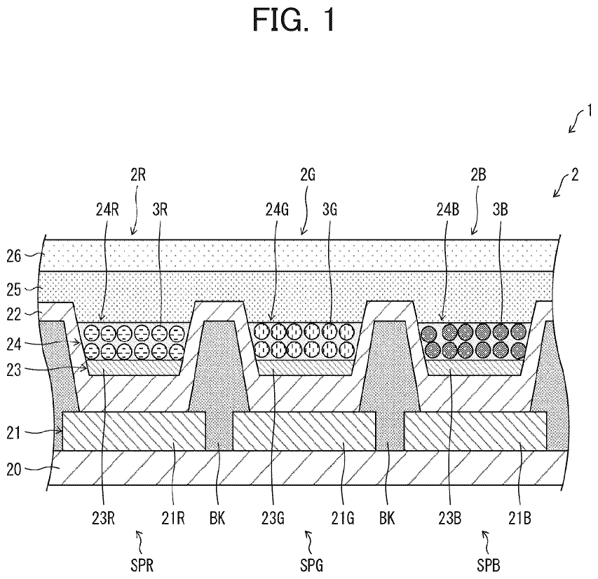

A detailed description is now given of the structure of the display section DA of the display device 1 in accordance with the present embodiment with reference to FIG. 1. FIG. 1 is a schematic cross-sectional side view of a display device in accordance with the present embodiment and is a cross-sectional view taken along line I-I shown in FIG. 2. In particular, FIG. 1, in a plan view of the display device 1 in accordance with the present embodiment, illustrates a cross-section that passes through a blue subpixel SPB, a green subpixel SPG, and a red subpixel SPR (detailed later). In the disclosure, in some cases, the direction from a substrate 20 toward a cathode 26 (detailed later) in the display device 1 may be described as “upward”, and the opposite direction may be described as “downward.”

Referring to FIG. 1, the display device 1 includes light-emitting elements 2. The light-emitting elements 2 include blue light-emitting elements 2B, green light-emitting elements 2G, and red light-emitting elements 2R (detailed later). The display device 1 includes an array of blue subpixels SPB in which the blue light-emitting elements 2B are provided, green subpixels SPG in which the green light-emitting elements 2G are provided, and red subpixels SPR in which the red light-emitting elements 2R are provided. The blue light-emitting elements 2B, the green light-emitting elements 2G, and the red light-emitting elements 2R individually emit blue light, green light, and red light respectively. Hence, the display device 1 produces a color display by, for example, individually controlling the above-described light-emitting elements by using, for example, a driver (not shown).

Note that in the present embodiment, blue light refers to light that has a central emission wavelength in the wavelength range of, for example, from 380 nm to 500 nm both inclusive. In addition, green light refers to light that has a central emission wavelength in the wavelength range of, for example, from 500 nm exclusive to 600 nm inclusive. Furthermore, red light refers to light that has a central emission wavelength in the wavelength range of from 600 nm exclusive to 780 nm inclusive.

### Display Device: Light-Emitting Element: Overview

The light-emitting elements 2 include the substrate 20. For example, the substrate 20 may be assumed to be provided in a position where the substrate 20 overlaps the display section DA and the frame section NA in a plan view of the display device 1, and the light-emitting elements 2 may be assumed to be provided to have a portion where this portion overlaps the display section DA of the substrate 20 in a plan view of the display device 1. In other words, the substrate 20 may be provided across the display section DA and the frame section NA in a plan view of the display device 1. The substrate 20 may have a top face that is substantially parallel to the display surface of the display device 1, in other words, the substrate 20 and the display device 1 may have a substantially identical plan view.

Furthermore, the light-emitting elements 2 include an anode 21 as a first electrode, a hole transport layer 22, an intermediate layer 23 as a first intermediate layer, a light-emitting layer 24, an electron transport layer 25, and the cathode 26 as a second electrode, all of which are provided on the substrate 20 in this order. It should be understood however that in the present embodiment, the layers on the substrate 20 of the light-emitting elements 2 may have a different structure so long as the intermediate layer 23 is positioned closer to the substrate 20 than is the light-emitting layer 24. For example, the light-emitting elements 2 may include the cathode 26 as the first electrode, the electron transport layer 25, the intermediate layer 23 as the first intermediate layer, the light-emitting layer 24, the hole transport layer 22, and the anode 21 as the second electrode, all of which are provided on the substrate 20 in this order. Furthermore, the light-emitting elements 2 may include a hole injection layer between the anode 21 and the hole transport layer 22 or include an electron injection layer between the electron transport layer 25 and the cathode 26.

The light-emitting elements 2 may be individually provided in the above-described plurality of subpixels respectively. In addition, the display device 1 may include, for example, a driver (not shown) in a position where the driver would overlap the frame section NA of the substrate 20 in a plan view. The substrate 20 may include pixel circuits (not shown) correspondingly to the subpixels. The pixel circuit may be connected electrically to the anode 21 of the light-emitting element 2. The display device 1 may control the emission of light by each light-emitting element 2 by controlling the application of voltage to the anode 21 by each pixel circuit through the control of, for example, a driver.

### Display Device: Light-Emitting Element: Electrode

At least either one of the anode 21 and the cathode 26 is a transparent electrode transparent to visible light. As the transparent electrode, for example, ITO, InZnO, SnO₂, or FTO may be used. In addition, either one of the anode 21 and the cathode 26 may be a reflective electrode. The reflective electrode may contain a metal material with a high visible light reflectance, and this metal material may be, for example, either an elementary substance such as Al, Ag, Cu, or Au or an alloy of any of these substances.

### Display Device: Light-Emitting Element: Charge Transport Layer

The hole transport layer 22 is a layer for transporting the holes injected from the anode 21 toward the light-emitting layer 24. The hole transport layer 22 is electrically connected to each anode 21 via an opening in a bank BK (detailed later). The hole transport layer 22 may be made of an organic or inorganic hole-transportable material that has been used in, for example, light-emitting elements containing quantum dots in the related art. Examples of materials for the hole transport layer 22 include poly[(9,9-dioctylfluorenyl-2,7-diyl)-co-(4,4′-(N-4-sec-butylphenyl))diphenylamine)] (“TFB”), poly[N,N′-bis(4-butylphenyl)-N,N′-bis(phenyl)-benzidine] (“poly-TPD”), and polyvinyl carbazole (“PVK”). Any one of these materials may be used alone, and any two or more of them may be suitably mixed or stacked in use.

The electron transport layer 25 is a layer for transporting the electrons injected from the cathode 26 to the light-emitting layer 24. The electron transport layer 25 may be made of an organic or inorganic electron-transportable material that has been used as an electron transport material in, for example, light-emitting elements containing quantum dots in the related art. Examples of electron transport materials may include 2,2′,2″-(1,3,5-benzinetriyl)-tris(1-phenyl-1-H-benzimidazole) (“TPBi”), 2,9-dimethyl-4,7-diphenyl-1,10-phenanthroline (“BCP”), and 4,7-diphenyl-1,10-phenanthroline (“Bphen”). Alternatively, the electron transport layer 25 may include, as an electron transport material, zinc oxide (ZnO), titanium oxide (TiO₂), or zirconium oxide (ZrO₂) in non-nanoparticle, bulk form. The bulk zinc oxide (ZnO) may be doped with at least one of Li, Mg, Al, Ti, Ga, and Zr. The electron transport material may contain any one of these materials and may contain any suitable two or more of them. The electron transport layer 25 may contain nanoparticles containing any of these inorganic electron transport materials.

When the light-emitting element 2 includes a hole injection layer, the hole injection layer may contain the above-described hole-transportable material. When the light-emitting element 2 includes an electron injection layer, the electron injection layer may contain the above-described electron-transportable material.

### Display Device: Light-Emitting Element: Intermediate Layer

The intermediate layer 23 is in contact with a face of the light-emitting layer 24 that faces the substrate 20 and has a function of planarizing, by the mechanism detailed later, a face on which the light-emitting layer 24 is formed. In particular, in the present embodiment, the intermediate layer 23 functions as a base layer in forming the light-emitting layer 24. The intermediate layer 23 contains a novolac-type phenol resin. In the present embodiment, the novolac-type phenol resin contained in the intermediate layer 23 may have the following general formula.

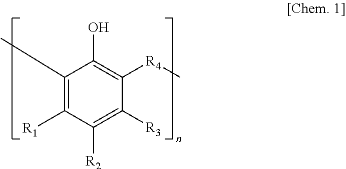

In this general formula, n is an integer of from 1 to 4, both inclusive. Each of R₁, R₂, and R₃ is either a C₁-C₄ alkyl group with or without a substituent or a H. In other words, each of R₁, R₂, and R₃ may be an alkyl group in which at least one hydrogen is replaced by a substituent. R₄ is a C₁-C₃ aliphatic compound containing an alkylene group with or without a substituent. For example, R₄ may be an alkylene group in which at least one hydrogen is replaced by a substituent.

Note that the intermediate layer 23 may contain 20 vol % or more novolac-type phenol resin and may meanwhile contain, for example, other additives. The intermediate layer 23 may contain, for example, a photosensitive resin. The density of the novolac-type phenol resin contained in the intermediate layer 23 may be calculated from the areal ratio of the novolac-type phenol resin in the cross-section of the intermediate layer 23. For example, the areal ratio of the novolac-type phenol resin may be greater than or equal to 18% in the cross-section of the intermediate layer 23.

With a view to increase the film-forming property of the intermediate layer 23 and additionally to improve the function of planarizing the face on which the light-emitting layer 24 is formed (detailed later), the intermediate layer 23 may have a thickness of at least 5 nm. In addition, with a view to sufficiently cause tunnelling of holes from the hole transport layer 22 to the light-emitting layer 24 via the intermediate layer 23 and to reduce the overall electrical resistance of the light-emitting element 2, the intermediate layer 23 may have a thickness of less than or equal to 20 nm.

### Display Device: Light-Emitting Element: Light-Emitting Layer

The light-emitting layer 24 contains a light-emitting material that emits light when excited by excitons generated by the recombination of the holes injected from the anode 21 and the electrons injected from the cathode 26. The light emitted by the light-emitting layer 24 is extracted through, for example, a transparent electrode that is either one or both of the anode 21 and the cathode 26.

For instance, the light-emitting layer 24 contains a plurality of quantum dots as a light-emitting material. Each quantum dot in the light-emitting layer 24 may have a core/shell structure that includes: a core that emits light when excited by the above-described excitons; and a shell formed around this core to protect the core. In addition, in the present embodiment, the light-emitting layer 24 contains organic or inorganic ligands that are coordinated to these quantum dots by forming coordinate bonds with the outermost circumferential faces of the quantum dots.

Note that in the disclosure, “quantum dots” refers to dots that have a maximum width of less than or equal to 100 nm. The shape of the quantum dots is not limited in any particular manner so long as they satisfy this maximum width and is not necessarily limited to a three-dimensional spherical shape (circular cross-sectional shape). The quantum dots, for example, may be shaped with a polygonal cross-section, may have a virgulate three-dimensional shape or a ramal three-dimensional shape, may have three-dimensional shape with an irregular surface, or may have a shape that is a combination of these shapes.

The quantum dots are generally preferably composed of a semiconductor. The semiconductor preferably has a certain bandgap. The semiconductor is preferably a material that is capable of emitting light and in addition preferably contains a material detailed below. The semiconductor is preferably capable of emitting blue, green, and red light respectively. The semiconductor, for example, contains at least one species selected from the group consisting of Group II-VI compounds, Group III-V compounds, chalcogenide, and perovskite compounds. Note that “Group II-VI compounds” refers to compounds containing a Group II element and a Group VI element, and “Group III-V compounds” refers to compounds containing a Group III element and a Group V element. In addition, a Group II element may contain a Group 2 element and a Group 12 element, a Group III element may contain a Group 3 element and a Group 13 element, a Group V element may contain a Group 5 element and a Group 15 element, and a Group VI element may contain a Group 6 element and a Group 16 element.

The Group II-VI compound contains at least one species selected from the group consisting of, for example, MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe.

The Group III-V compound contains at least one species selected from the group consisting of, for example, GaAs, GaP, InN, InAs, InP, and InSb.

Chalcogenide is a compound containing a Group VI A (16) element and, for example, includes CdS or CdSe. Chalcogenide may contain a mixed crystal of these materials.

Perovskite compounds have a composition of, for example, a general formula, CsPbX₃. The component element X includes, for example, at least one species selected from the group consisting of Cl, Br, and I.

Here, the numbering of groups of elements using Roman numerals is based on the defunct IUPAC (International Union of Pure and Applied Chemistry) system or the defunct CAS (Chemical Abstracts Service) system, and the numbering of groups of elements using Arabic numerals is based on the current IUPAC system.

In the present embodiment, the plurality of quantum dots in each light-emitting layer 24 may form a superlattice structure in which the plurality of quantum dots are arranged in a particular pattern with each quantum dot being separated by substantially constant distances from the surrounding quantum dots. In particular, in each light-emitting layer 24, the plurality of quantum dots may have a superlattice structure in which the centers of the cores are arranged in such a three-dimensional pattern as to be positioned at substantially the same sites as virtual lattice points.

Note that the light-emitting layer 24 is not necessarily have the above-described structure so long as the light-emitting layer 24 contains a light-emitting material that emits light due to the holes from the anode 21 and the electrons from the cathode 26. For example, the light-emitting layer 24 may contain an organic light-emitting material, in which case the display device 1 may be an OLED display device including OLEDs (organic light-emitting diodes) as the light-emitting elements 2.

### Display Device: Light-Emitting Element: Bank

Furthermore, the light-emitting element 2 includes the bank BK on the substrate 20. The bank BK contains, for example, an electrically insulating resin material including, for example, polyimide. The bank BK partitions each of the anode 21, the intermediate layer 23, and the light-emitting layer 24 in the light-emitting element 2 for the red subpixel SPR, the green subpixel SPG, and the blue subpixel SPB in a plan view of the substrate 20. In the present embodiment, the hole transport layer 22, the electron transport layer 25, and the cathode 26 are provided commonly across the above-described plurality of subpixels. It should be understood however that the hole transport layer 22, the electron transport layer 25, and the cathode 26 may also be partitioned by the bank BK for each subpixel.

In the present embodiment, in particular, the light-emitting layer 24 is partitioned by the bank BK into a red light-emitting layer 24R in the red subpixel SPR, a green light-emitting layer 24G in the green subpixel SPG, and a blue light-emitting layer 24B in the blue subpixel SPB. The red light-emitting layer 24R includes red light-emitting red quantum dots 3R. The green light-emitting layer 24G includes green light-emitting green quantum dots 3G. The blue light-emitting layer 24B includes blue light-emitting blue quantum dots 3B. The red quantum dots 3R, the green quantum dots 3G, and the blue quantum dots 3B may have the mutually same structure, except for the color of the light that they emit.

Additionally, the anode 21 is partitioned by the bank BK into an anode 21R in the red subpixel SPR, an anode 21G in the green subpixel SPG, and an anode 21B in the blue subpixel SPB. In addition, the intermediate layer 23 is partitioned by the bank BK into an intermediate layer 23R in the red subpixel SPR, an intermediate layer 23G in the green subpixel SPG, and an intermediate layer 23B in the blue subpixel SPB.

It should be understood however that the anode 21 and the intermediate layer 23 may have the same structure regardless of the color of the light emitted by the subpixels in which they are formed. Alternatively, the anode 21 and the intermediate layer 23 may contain a different material between subpixels in accordance with the bandgap of the light-emitting layer 24 in the same subpixel.

Therefore, in the present embodiment, the red light-emitting element 2R in the red subpixel SPR includes the anode 21R, the hole transport layer 22, the intermediate layer 23R, the red light-emitting layer 24R, the electron transport layer 25, and the cathode 26. In addition, the green light-emitting element 2G in the green subpixel SPG includes the anode 21G, the hole transport layer 22, the intermediate layer 23G, the green light-emitting layer 24G, the electron transport layer 25, and the cathode 26. Furthermore, the blue light-emitting element 2B in the blue subpixel SPB includes the anode 21B, the hole transport layer 22, the intermediate layer 23B, the blue light-emitting layer 24B, the electron transport layer 25, and the cathode 26.

The bank BK may be provided in a position where the bank BK can cover the edge of each anode 21. In other words, the bank BK may have an opening in a part of its portion where the bank BK overlaps each anode 21 in a plan view of the substrate 20. When this is the case, the bank BK can reduce the influence of the concentration of electric field at the edge of the anode 21 on the injection of holes from the anode 21 to the light-emitting layer 24 in each light-emitting element 2.

### Display Device: Supplementary Description

Note that the display device 1 may include, in a layer overlying the light-emitting element 2, for example, an organic or inorganic sealing layer for sealing the light-emitting element 2 or a capping layer for improving the light extraction efficiency from the light-emitting element 2. In addition, the display device 1 may include, in a layer overlying the light-emitting element 2, a touch panel unit for enabling the display device 1 to function as a touch-panel display device.

### Method of Manufacturing Display Device: Up to Formation of Hole Transport Layer

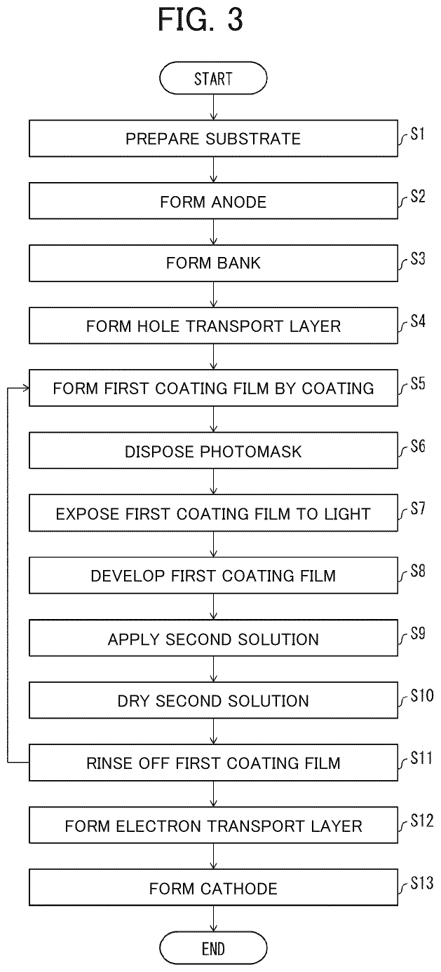

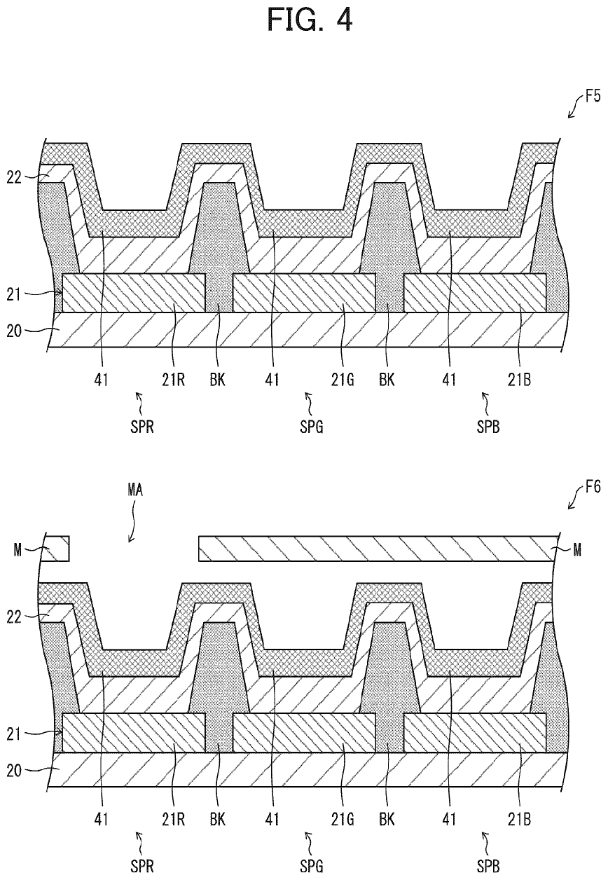

Referring to FIGS. 3 to 7, a description is now given of a method of manufacturing the light-emitting elements 2 in accordance with the present embodiment. FIG. 3 is a flow chart representing a method of manufacturing the light-emitting elements 2 in accordance with the present embodiment. FIGS. 4 to 7 are schematic step-specific cross-sectional illustrations of the method of manufacturing the light-emitting elements 2 in accordance with the present embodiment, showing a cross-section corresponding to the cross-section shown in FIG. 1.

In the method of manufacturing the light-emitting elements 2 in accordance with the present embodiment, first, the substrate 20 is prepared (step S1). The substrate 20 may be prepared by, for example, cutting, for example, a glass substrate or a film substrate into a prescribed shape. Alternatively, a large-sized substrate 20 may be prepared and cut into the plurality of light-emitting elements 2 after performing steps. Step S1 may include a step of forming pixel circuits in sites corresponding to the subpixels on the substrate 20 and may additionally include a step of forming, for example, a driver on the substrate 20.

Next, the anode 21 is formed on the substrate 20 (step S2). The anode 21 may be formed by, for example, forming a thin film of, for example, a metal material on the substrate 20 by, for example, sputtering and thereafter patterning the thin film by, for example, dry etching.

Next, the bank BK is formed on the substrate 20 and on the anode 21 (step S3). The bank BK may be formed by, for example, applying a photosensitive resin material onto the substrate 20 and onto the anode 21 to form a film and thereafter forming an opening in a position overlapping the anode 21 in a plan view of the substrate 20 by, for example, photolithography.

Next, the hole transport layer 22 is formed on the anode 21 (step S4). The hole transport layer 22 may be formed by, for example, applying a hole-transportable material between the bank BK and the bank BK and also onto the anode 21 in a plan view of the substrate 20 by, for example, inkjet technology, to form a film. Alternatively, the hole transport layer 22 may be formed by, for example, applying a hole-transportable material onto the anode 21 and onto the bank BK by, for example, spin-coating, to form a film.

### Method of Manufacturing Display Device: Forming Intermediate Layer

Next, in the present embodiment, a part of the intermediate layer 23 is formed. In particular, in the present embodiment, first, a description is given of an example in which the intermediate layer 23R, which is a part of the intermediate layer 23 that is positioned in the red subpixel SPR, is formed.

First, as shown in a step-specific cross-sectional illustration F5 in FIG. 4, a first solution is applied onto the hole transport layer 22 and the bank BK to form a first coating film (step S5). The first solution contains, for example: a plurality of phenolic compounds as a monomer that is a precursor to a novolac-type phenol resin; and a positive photosensitive resin. The first solution may contain a photocatalyst that functions as a condensation polymerization initiator for the foregoing phenolic compounds when exposed to light. In particular, in step S5, as shown in the step-specific cross-sectional illustration F5, the first coating film 41 is formed commonly to the plurality of subpixels. The first coating film 41 may be formed by, for example, various printing or coating technology including spin-coating. In step S5, the first coating film 41 may be formed by heating the applied first solution to evaporate the medium.

More specifically, for example, in step S5, the applied first solution is a solution containing phenolic compounds, a photosensitive resin, and a surfactant. In step 5, this solution is applied by spin-coating. In this spin-coating, the solution is applied, for example, while the stack body including the substrate 20 is being accelerated to a rotational speed of 800 rpm over 5 seconds. Thereafter, the applied solution is heated at 90° C. for 3 minutes to form the first coating film 41.

Next, as shown in a step-specific cross-sectional illustration F6 in FIG. 4, a photomask M is disposed above the applied first coating film 41 opposite the substrate 20 (step S6). The photomask M may be, for example, a mask for blocking ultraviolet light. Here, in a case of a step of forming the intermediate layer 23R and the red light-emitting layer 24R, the photomask M is disposed in step S6 so that a transparent portion MA having an opening that transmits, for example, ultraviolet light resides in a position overlapping the red subpixel SPR.

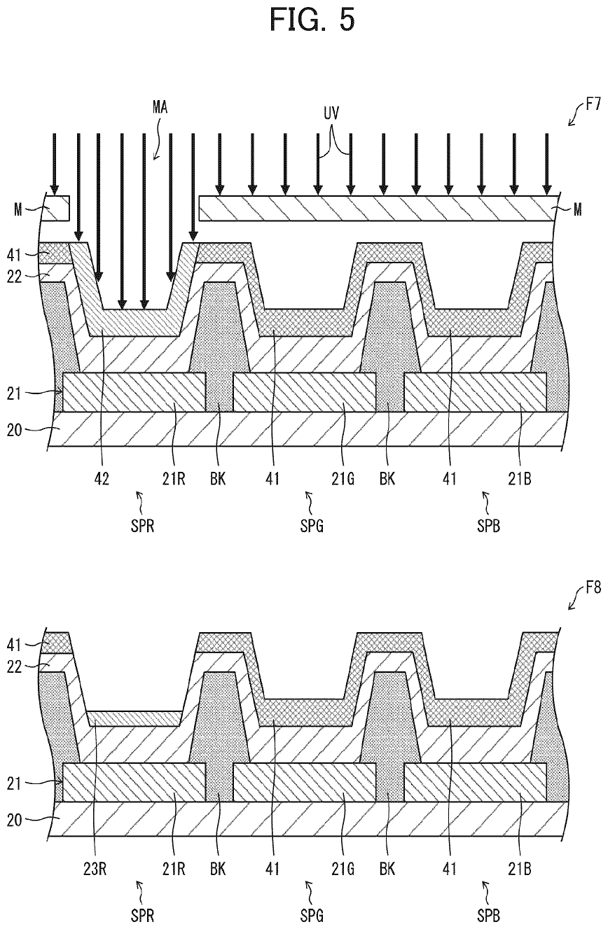

Next, as shown in a step-specific cross-sectional illustration F7 in FIG. 5, a part of the applied first coating film 41 is exposed to light by projecting, for example, ultraviolet light UV from above the photomask M opposite the substrate 20 (step S7). The ultraviolet light UV is blocked by the photomask M. Therefore, no ultraviolet light UV is projected onto the first coating film 41 positioned in the green subpixel SPG and the blue subpixel SPB. In contrast, the ultraviolet light UV transmits through the transparent portion MA of the photomask M. Therefore, in step S7, ultraviolet light UV is projected only onto the first coating film 41 positioned in the red subpixel SPR. For example, the exposure intensity in step S7 is 200 mJ/cm².

Step S7 changes the first coating film 41 positioned in the red subpixel SPR and irradiated with ultraviolet light UV into the exposed first coating film 42, as shown in the step-specific cross-sectional illustration F7 in FIG. 5. In particular, in step S7, the photosensitive resin contained in the exposed first coating film 41 is modified, which improves the solubility of the first coating film 42 in a development solution (detailed later). Furthermore, the phenolic compounds containing the exposed first coating film 41 start condensation polymerization via a photocatalyst to form a novolac-type phenol resin in the first coating film 42. In particular, the first coating film 42 has the same structure as the above-described intermediate layer 23R, except for its thickness.

Next, the first coating film 41 is developed by rinsing the first coating film 41 and the first coating film 42 in a suitable developer (step S8). Here, the unexposed first coating film 41 is insoluble in the development solution, whereas the exposed first coating film 42 is soluble in the development solution. Therefore, in step S8, only the first coating film 42 positioned in the red subpixel SPR dissolves in the development solution.

More specifically, for example, in step S8, puddle development is performed. In this puddle development, the first coating film 41 is rinsed 5 times in a development solution containing 0.6 mass % TMAH and thereafter rinsed once in water.

Here, in the present embodiment, in the development step of step S8, only a part of the first coating film 42 positioned in the red subpixel SPR is removed. Hence, in step S8, the first coating film 42 is retained up to a prescribed thickness from the top face of the hole transport layer 22 in the red subpixel SPR. The first coating film 42 may be retained by, for example, increasing the thickness of the first coating film 41 in step S5, either reducing the exposure intensity or shortening the exposure time in step S7, or shortening the rinse time in a development solution in step S8. Therefore, in step S8 in accordance with the present embodiment, as shown in a step-specific cross-sectional illustration F8 in FIG. 5, the first coating film 42 is retained as the intermediate layer 23R in the red subpixel SPR. The intermediate layer 23R is hence formed.

### Method of Manufacturing Display Device: Forming Coating Film Containing Quantum Dots

Next, in the present embodiment, a part of the light-emitting layer 24 is formed. In particular, in the present embodiment, first, a description is given of an example in which the red light-emitting layer 24R, which is a part of the light-emitting layer 24 that is positioned in the red subpixel SPR, is formed.

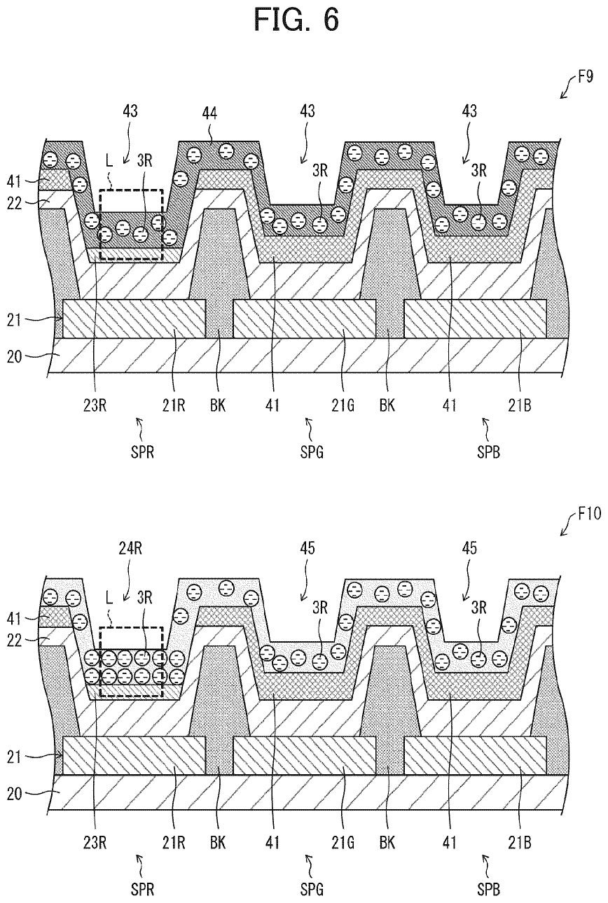

First, as shown in a step-specific cross-sectional illustration F9 in FIG. 6, a second solution 43 is applied onto the intermediate layer 23R and the first coating film 41, both of which are already provided (step S9). The second solution 43 is, for example, a solution in which the red quantum dots 3R and the ligands capable of being coordinated to these red quantum dots 3R are dispersed in a second medium 44. The second solution 43 may be produced by, for example, synthesizing the red quantum dots 3R in the second medium 44 by various methods and then adding the ligands. The second solution 43 is formed commonly to the plurality of subpixels by, for example, various methods including spin-coating.

Next, the applied second solution 43 is dried (step S10). The second solution 43 may be dried by, for example, heating the second solution 43 or leaving the second solution 43 to stand for a prescribed time, to evaporate the second medium 44 in the second solution 43. Hence, the second medium 44 in the applied second solution 43 evaporates, thereby forming a second coating film 45 as shown in a step-specific cross-sectional illustration F10 in FIG. 6. Here, in the red subpixel SPR, a superlattice structure of the red quantum dots 3R is formed by a mechanism (detailed later).

### Method of Manufacturing Display Device: Mechanism of Forming Superlattice Structure of Quantum Dots

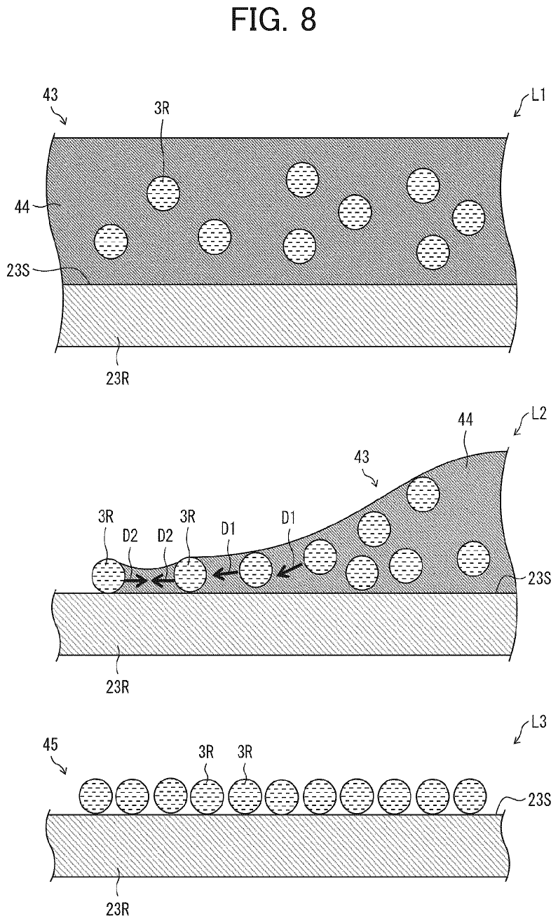

The mechanism by which the superlattice structure of the red quantum dots 3R is formed in step S10 is now described in detail with reference to FIG. 8. A schematic view L1, a schematic view L2, and a schematic view L3 in FIG. 8 are enlarged schematic views of a part of the step-specific cross-sectional illustration F9 and the step-specific cross-sectional illustration F10 in step S9 and step S10 in accordance with the present embodiment. In particular, the schematic view L1, the schematic view L2, and the schematic view L3 in FIG. 8 are enlarged schematic views of a region L shown in the step-specific cross-sectional illustration F9 and the step-specific cross-sectional illustration F10, in other words, of a vicinity of the top face of the intermediate layer 23R. The schematic view L1, the schematic view L2, and the schematic view L3 in FIG. 8 depict step S9 or step S10 at mutually different points in time.

In step S9, the second solution 43 is already applied in a position including a top face 23S of the intermediate layer 23R. Therefore, in step S9, the second solution 43, in which the red quantum dots 3R are dispersed in the second medium 44, is in contact with the top face 23S of the intermediate layer 23R as shown in the schematic view L1 in FIG. 8.

Here, in step S10, the second medium 44 in the applied second solution 43 gradually evaporates. In particular, in step S10, the evaporation of the second medium 44 starts on the exterior of the second solution 43 and progresses gradually toward the interior. As the second medium 44 starts evaporating on the exterior of the second solution 43, the second medium 44 subsequently starts flowing from the center of the second solution 43 toward the exterior of the second solution 43.

Therefore, in step S10, even in the vicinity of the top face 23S of the intermediate layer 23, the second medium 44 in the second solution 43 starts evaporating on one of its two ends, and furthermore, the second medium 44 starts flowing on this one of the two ends. Therefore, in step S10, as shown in the schematic view L2, the thickness of the second medium 44 in the second solution 43 decreases on one of its two sides, and the second medium 44 flows toward this one of the two sides.

Here, as a result of the flow of the second medium 44, the red quantum dots 3R in the second solution 43 flow in a first direction D1 that is parallel to the direction of the flow of the second medium 44. Therefore, the red quantum dots 3R in the second solution 43 move to an edge of the second solution 43 where the second medium 44 is thin. Near the edge of the second solution 43, the second medium 44 evaporates in locations between the plurality of red quantum dots 3R. Hence, a horizontal capillary force is exerted on these plurality of red quantum dots 3R in such a second direction D2 that the plurality of red quantum dots 3R are moved closer to each other. Therefore, in step S10, the red quantum dots 3R are arranged in a particular pattern, sequentially and starting with the edge side of the second solution 43 in which the second medium 44 evaporates. By hence completing step S10 and completing the formation of the second coating film 45, the superlattice structure of the red quantum dots 3R is formed on the top face 23S of the intermediate layer 23R, in other words, in the red subpixel SPR.

Here, the flow of the second medium 44 toward the edge side of the second solution 43 and the accompanying flow of the red quantum dots 3R, both detailed above, tend to be more efficiently generated with a higher degree of planarity of the top face 23S on which the second medium 44 resides. In addition, the novolac-type phenol resin is a polymer of monomers in which phenol molecules and a methylene chain are bonded together and tends to have the hydroxy groups in the phenol aligned in polymerization. Therefore, the top face 23S of the intermediate layer 23R, which is a thin film containing a novolac-type phenol resin, tends to have a high degree of planarity. Therefore, the high degree of planarity of the top face 23S of the intermediate layer 23R allows the superlattice structure of the red quantum dots 3R to be formed on the intermediate layer 23R with increased precision.

Furthermore, the horizontal capillary force between the plurality of red quantum dots 3R in the second solution 43 depends on, for example, hydrophobic interaction, electrostatic interaction, or van der Waals force between the plurality of red quantum dots 3R. Here, the novolac-type phenol resin improves hydrophobic interaction or electrostatic interaction between the above-described plurality of red quantum dots 3R by the repeated structure of the phenol molecules and the methylene chain. Therefore, the superlattice structure of the red quantum dots 3R is formed on the intermediate layer 23R with further increased precision.

Note that in step S10, the superlattice structure of the red quantum dots 3R is not necessarily formed, for example, on the top face of the unexposed, first coating film 41 except for the top face 23S of the intermediate layer 23R. Therefore, in step S10, the planarity of the top face of the unexposed, first coating film 41 in sites excluding the red subpixel SPR is not particularly required from the standpoint of forming the superlattice structure of the red quantum dots 3R in the red subpixel SPR.

### Method of Manufacturing Display Device: Patterning Coating Film Containing Quantum Dots

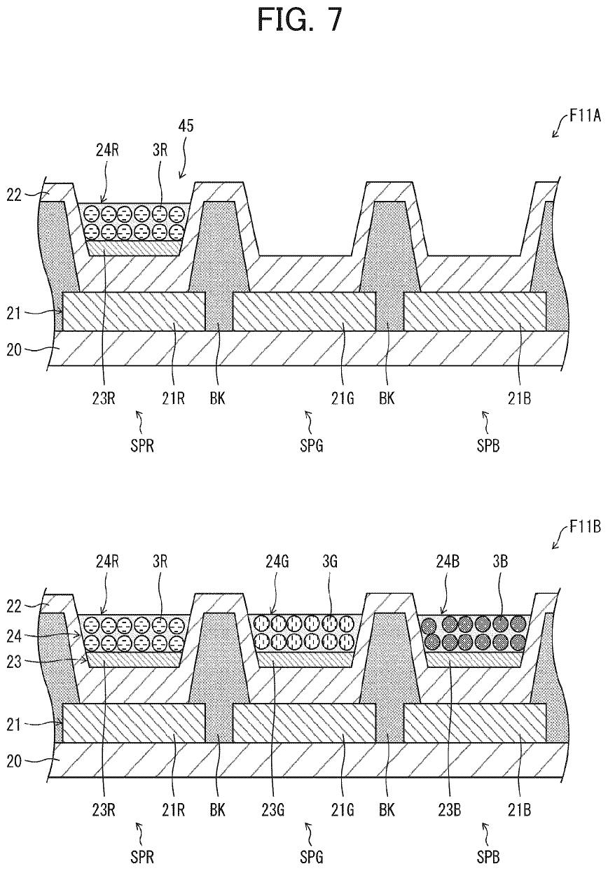

Subsequent to the formation of the second coating film 45 and the formation of the superlattice structure of the red quantum dots 3R in the red subpixel SPR, the unexposed, residual first coating film 41 is rinsed off in a suitable rinsing liquid (step S11). This rinsing liquid contains, for example, a medium in which the first coating film 41 is soluble. Hence, as shown in a step-specific cross-sectional illustration F11A in FIG. 7, the first coating film 41, formed in sites including the green subpixel SPG and the blue subpixel SPB, is removed. Hence, the part of the second coating film 45 that is positioned on the first coating film 41 is removed.

Here, the intermediate layer 23R, which is a part of the exposed, first coating film 42, is insoluble in the rinsing liquid. Alternatively, since the intermediate layer 23R is thinner than the unexposed, first coating film 41, it is difficult to remove the second coating film 45 on the intermediate layer 23R even by the rinsing. Therefore, as shown in the step-specific cross-sectional illustration F11A in FIG. 7, the second coating film 45 remains in the red subpixel SPR. The red light-emitting layer 24R, which has the superlattice structure of the red quantum dots 3R, is hence formed on the intermediate layer 23R as shown in the step-specific cross-sectional illustration F11A in FIG. 7. In other words, in step S10, the part that overlaps the intermediate layer 23R in a plan view provides at least a part of the light-emitting layer 24.

Thereafter, step S5 to step S11 are repeatedly performed while partially altering the process. Here, in step S6, the position of the transparent portion MA of the photomask M is altered in accordance with the position of the subpixel including the intermediate layer 23 and the light-emitting layer 24 to be formed. When this is the case, in step S10, the second coating film 45 is formed on the top face of the intermediate layer 23G or the intermediate layer 23B.

Hence, as shown in a step-specific cross-sectional illustration F11B in FIG. 7, the intermediate layer 23G and the green light-emitting layer 24G, which has a superlattice structure of the green quantum dots 3G on the top face of the intermediate layer 23G, are formed in the green subpixel SPG. Likewise, the intermediate layer 23B and the blue light-emitting layer 24B, which has a superlattice structure of the blue quantum dots 3B on the top face of the intermediate layer 23B, are formed in the blue subpixel SPB. The step of forming the intermediate layer 23 and the light-emitting layer 24 is hence completed.

Note that in step S11, which is one of the steps of forming the red light-emitting layer 24R, the unexposed, first coating film 41 may partially remain also in the green subpixel SPG and the blue subpixel SPB. When this is the case, in step S7, which is one of the subsequent steps of forming each light-emitting layer 24, the remaining first coating film 41 may be exposed to light together with the newly applied, first coating film 41 and may become a part of the exposed, first coating film 42.

### Method of Manufacturing Display Device: Formation of Electron Transport Layer and Subsequent Steps

Subsequent to the formation of the intermediate layer 23 and the light-emitting layer 24, the electron transport layer 25 is formed on the light-emitting layer 24 (step S12). The electron transport layer 25 may be formed, for example, similarly to step S4, by applying, and hence forming a film of, an electron-transportable material in sites including on the light-emitting layer 24.

Next, the cathode 26 is formed on the electron transport layer 25 (step S13). The cathode 26 may be formed by, for example, forming a thin film of, for example, a metal material on the electron transport layer 25 by, for example, sputtering. The cathode 26 may be formed so as to electrically connect to the above-described auxiliary power source. The process of manufacturing the display device 1 is hence completed.

### Effects Achieved by Display Device

The display device 1 in accordance with the present embodiment includes: the light-emitting layer 24; and the light-emitting elements 2 containing the intermediate layer 23 that is in contact with the light-emitting layer 24. Since the intermediate layer 23 contains a novolac-type phenol resin, as described above, the top face 23S of the intermediate layer 23, which is in contact with the light-emitting layer 24, exhibits improved planarity, thereby improving the closeness of the intermediate layer 23 and the light-emitting layer 24. Therefore, the luminous efficiency of the light-emitting elements 2 is improved by the reduction of the local luminescence of the light-emitting layer 24 caused by the local contact of the intermediate layer 23 with the light-emitting layer 24.

The display device 1, which includes the light-emitting elements 2 in accordance with the present embodiment with improved luminous efficiency, is capable of producing displays by driving the light-emitting elements 2 with lower voltage and is for this reason capable of reducing power consumption. In addition, the display device 1 has less need to drive the light-emitting elements 2 with a voltage that is so high as to accelerate degradation of the light-emitting layer 24 and for this reason has a longer lifespan.

The light-emitting element 2 in accordance with the present embodiment includes the intermediate layer 23 which is closer to the substrate 20 than is the light-emitting layer 24. Therefore, a possible method of forming the light-emitting elements 2 is to, for example, form the layers of the light-emitting elements 2 sequentially on the substrate 20 as described in the present embodiment. When this is the case, in the present embodiment, the light-emitting layer 24 is formed on the top face 23S of the intermediate layer 23. Therefore, the planarity of the top face 23S of the intermediate layer 23 is improved, and for this reason, the planarity of the face on which the light-emitting layer 24 is provided is improved, which further improves the closeness of the intermediate layer 23 and the light-emitting layer 24. Therefore, the light-emitting elements 2 in accordance with the present embodiment further improve luminous efficiency.

In particular, the light-emitting layer 24 in the light-emitting elements 2 in accordance with the present embodiment contains quantum dots as a light-emitting material. In addition, the step of forming the light-emitting layer 24 involves applying the second solution 43 onto the intermediate layer 23 and forming the second coating film 45 by drying the second solution 43. Therefore, the planarity of the top face 23S of the intermediate layer 23 is improved in the step of forming the light-emitting layer 24, which facilitates the formation of the superlattice structure of the quantum dots. Therefore, the mutual adherence between the quantum dots in the light-emitting layer 24 is improved, and for this reason, the light-emitting elements 2 are capable of reducing leakage current that flows between the plurality of quantum dots in the light-emitting layer 24. Therefore, the luminous efficiency of the light-emitting elements 2 is further improved.

Note that the light-emitting layer 24 in the present embodiment contains ligands capable of being coordinated to quantum dots. In other words, in the step of forming the light-emitting layer 24 in accordance with the present embodiment, ligands are added to the solution in which quantum dots are dispersed. These ligands enhance the dispersibility of the quantum dots in the solution and reduces aggregation of the quantum dots, thereby restrains decreases in the luminous efficiency of the light-emitting layer 24.

In contrast, since the ligands enhance the dispersibility of the quantum dots in the solution, and therefore the adherence of the quantum dots in the solution is reduced. Here, in the present embodiment, since the planarity of the top face 23S of the intermediate layer 23 is high, the superlattice structure of the quantum dots is easily formed in the step of forming the light-emitting layer 24 even if the adherence of the quantum dots in the solution is low. Therefore, the light-emitting elements 2 are capable of restraining the ligands from reducing adherence between the quantum dots in the formed light-emitting layer 24. Therefore, the light-emitting elements 2 further improve luminous efficiency by maintaining both the reduction of the aggregation of the quantum dots in the light-emitting layer 24 and the improvement of the adherence of the quantum dots in the light-emitting layer 24.

The light-emitting elements 2 include the intermediate layer 23 between the anode 21 and the light-emitting layer 24. Therefore, the light-emitting elements 2 are capable of improving the efficiency of hole injection to the light-emitting layer 24 by improving adherence between the intermediate layer 23 and the light-emitting layer 24.

Generally, since, for example, the hole mobility is lower than the electron mobility in a light-emitting element including a light-emitting layer containing quantum dots as a light-emitting material, such a light-emitting element tends to be excessively rich in electrons where the concentration of the holes injected to the light-emitting layer is lower than the concentration of the electrons injected to the light-emitting layer. This excessive richness in electrons of the light-emitting layer may increase non-emissive processes or processes that can degrade the light-emitting material in the light-emitting layer, including the process of generating Auger electrons, and may reduce the luminous efficiency of the light-emitting element.

The light-emitting elements 2 reduce the excessive richness in electrons of the light-emitting layer 24 by improving the efficiency of hole injection to the light-emitting layer 24, thereby improving the charge-carrier balance in the light-emitting layer 24. Therefore, the light-emitting elements 2 more efficiently improve the luminous efficiency and furthermore reduce the progress of the degradation of the light-emitting layer 24, thereby extending the lifespan.

In addition, the light-emitting elements 2 include the hole transport layer 22 between the anode 21 and the intermediate layer 23. The light-emitting elements 2 are capable of improving adherence between the intermediate layer 23 and the light-emitting layer 24 regardless of the planarity of the top face of the hole transport layer 22 that faces the light-emitting layer 24. Therefore, the light-emitting elements 2 are capable of improving adherence between the intermediate layer 23 and the light-emitting layer 24 regardless of, for example, the material(s) contained in the hole transport layer 22 and the method of forming the hole transport layer 22. For example, when the hole transport layer 22 contains nanoparticles as a hole-transportable material, there are cases where the planarity of the top face of the hole transport layer 22 decreases because the top face of the hole transport layer 22 reflects the shape of each nanoparticle. Even in such cases, the light-emitting elements 2 are capable of improving adherence between the intermediate layer 23 and the light-emitting layer 24. Therefore, the light-emitting elements 2 achieve both freedom in the material of the hole transport layer 22 and in the method of manufacturing the hole transport layer 22 and improvement of the luminous efficiency.

In the present embodiment, the intermediate layer 23 contains a photosensitive resin. In other words, the first coating film 41 formed in the step of forming the intermediate layer 23 contains a photosensitive resin. Therefore, the intermediate layer 23 can be formed by patterning the first coating film 41 by photolithography in such a manner as to retain only parts of the exposed, first coating film 42.

This formation method improves precision of the formation position of the intermediate layer 23 over, for example, a method of selectively applying a material for the intermediate layer 23 by inkjet technology. Therefore, the formation method is capable of forming the intermediate layer 23 with a higher definition and is therefore capable of improving the resolution of the subpixels in the display device 1. In addition, the formation method improves the precision of the thickness of the intermediate layer 23 and also simplifies the step of forming the intermediate layer 23, over, for example, a method of selectively applying a material for the intermediate layer 23 by inkjet technology. Furthermore, since the first coating film 41 containing a photosensitive resin changes solubility significantly in the development solution depending on whether the first coating film 41 has or has not been exposed to light, it is possible to form a uniform and rigid film by photolithography using the first coating film 41. Therefore, the intermediate layer 23 containing a photosensitive resin and formed by photolithography can further improve the film-forming property of the light-emitting layer 24 formed on the top face.

In the present embodiment, the condensation polymerization of the phenolic compounds in the first coating film 41 is started by exposing the first coating film 41 to light in photolithography. Therefore, the step of separately performing condensation polymerization of the phenolic compounds in the first coating film 41 can be eliminated in the step of forming the intermediate layer 23, which simplifies the step of forming the intermediate layer 23.

In the step of forming the light-emitting layer 24 in accordance with the present embodiment, the second solution 43 is applied onto the formed intermediate layer 23 and the unexposed first coating film 41. Therefore, the patterning of the second coating film 45 formed from the second solution 43 can be performed together with the removal of the unexposed, first coating film 41. Therefore, the step of removing the unexposed parts of the first coating film 41, which is used to form the intermediate layer 23, is available for use in the patterning of the second coating film 45 for the purpose of forming the light-emitting layer 24, which simplifies the step of forming the intermediate layer 23 and the light-emitting layer 24. In addition, the aforementioned method does not require selectively applying a material for the light-emitting layer 24 in each subpixel by, for example, inkjet technology, which simplifies the step of forming the light-emitting layer 24.

Furthermore, according to this method, the residues of the exposed, first coating film 42, not completely rinsed off in the development solution in, and hence remaining from, the photolithography patterning of the first coating film 41, may be used as the intermediate layer 23. Therefore, the method can obviate the need for a separate step of forming the intermediate layer 23, which allows for further simplification of the step of forming the intermediate layer 23.

### Evaluating Light-Emitting Element

To evaluate the light-emitting element 2 in accordance with the present embodiment, light-emitting elements of Example 1 and Example 2 and light-emitting elements of Comparative Example 1 and Comparative Example 2 were manufactured, and their performance was measured and compared.

The light-emitting elements of Example 1 and Example 2 were manufactured under the above-described manufacturing conditions by the same method as the above-described method of manufacturing the light-emitting elements 2 in accordance with the present embodiment. It should be understood however that in the light-emitting element of Example 2, when compared with the light-emitting element of Example 1, the novolac-type phenol resin contained in the intermediate layer 23 was a modified novolac phenol resin. Here, the novolac-type phenol resin of Example 1 contained a H in place of each of R₁, R₂, and R₃ and a methylene group of the chemical formula below in place of R₄ in the foregoing general formula.

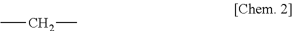

In addition, the modified novolac-type phenol resin of Example 2 contained a H in place of each of R₁, R₂, and R₃ and a dimethyl methylene group of the chemical formula below in place of R₄ in the general formula.

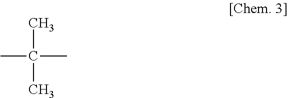

The light-emitting element of Comparative Example 1 included no intermediate layer 23 when compared with the light-emitting elements of Example 1 and Example 2. The light-emitting element of Comparative Example 1 was manufactured by a method in which the above-described method of manufacturing the light-emitting elements 2 in accordance with the present embodiment was partially altered. Specifically, in the method of manufacturing the light-emitting element of Comparative Example 1, the first solution applied in step S5 contained no phenolic compound, and additionally, the first coating film 42 was completely removed in step S8.

In the light-emitting element of Comparative Example 2, when compared with the light-emitting elements of Example 1 and Example 2, the intermediate layer 23 contained PMMA in place of a novolac-type phenol resin. The light-emitting element of Comparative Example 2 was manufactured by the same method as the above-described method of manufacturing the light-emitting elements 2 in accordance with the present embodiment, except that the first solution applied in step S5 was a precursor to PMMA instead of the phenolic compounds.

Performance of the light-emitting elements of Example 1, Example 2, Comparative Example 1, and Comparative Example 2 detailed above was measured and summarized in Table 1 below.

TABLE 1

| | | | | | External |
|---|---|---|---|---|---|
| | | | | | Quantum |
| | Intermediate Layer | | Film Surface Roughness [nm] | | Efficiency |
| | Present/Absent | Material | RMS | Rmax | EQE [%] |
| Example 1 | Present | Novolac-type | 0.58 | 4.08 | 6.0 |
| | | Phenol Resin | | | |
| Example 1 | Present | Modified | 0.61 | 4.16 | 5.9 |
| | | Novolac-type | | | |
| | | Phenol Resin | | | |
| C. Example 1 | Absent | — | 3.38 | 19.6 | 5.1 |
| C. Example 2 | Present | PMMA | 1.53 | 10.6 | 5.2 |

C. Example: Comparative Example

In Table 1, the “Present/Absent” column for the intermediate layer indicates the presence/absence of the intermediate layer 23 in each light-emitting element. When the light-emitting element includes an intermediate layer 23, the “Material” column for the intermediate layer gives the name of the material primarily contained in the intermediate layer 23.

In Table 1, the “Film Surface Roughness [nm]” column gives the film surface roughness of the base layer of the light-emitting layer 24 in each light-emitting element in nanometers. Therefore, the “Film Surface Roughness [nm]” column gives the roughness of the top face of the intermediate layer 23 for Example 1, Example 2, and Comparative Example 2 and gives the roughness of the top face of the hole transport layer 22 for Comparative Example 1. The “RMS” and “Rmax” columns under “Film Surface Roughness [nm]” give the square root of the average of squares of the roughness of the film surface and a maximum roughness of the film surface respectively. The roughness of the film surface was measured under the same conditions throughout the Examples and Comparative Examples.

In Table 1, the “External Quantum Efficiency EQE [%]” column gives the external quantum efficiency of each light-emitting element in % when the light-emitting element was driven with a current density of 50.0 mA/cm². The external quantum efficiency was measured by measuring the light-emission luminance of the light-emitting element in a square area with 4-mm sides as viewed in the stack direction of the light-emitting element.

The light-emitting elements of Example 1 and Example 2, when compared with the light-emitting element of Comparative Example 1, had a significantly reduced film surface roughness in the intermediate layer 23, which was a base layer for the light-emitting layer 24, and also had an improved external quantum efficiency. The light-emitting element of Comparative Example 2, when compared with the light-emitting element of Comparative Example 1, had a reduced film surface roughness in the intermediate layer 23, but its external quantum efficiency hardly changed.

### Embodiment 2

### Intermediate Layer Positioned on Cathode Side of Light-Emitting Layer

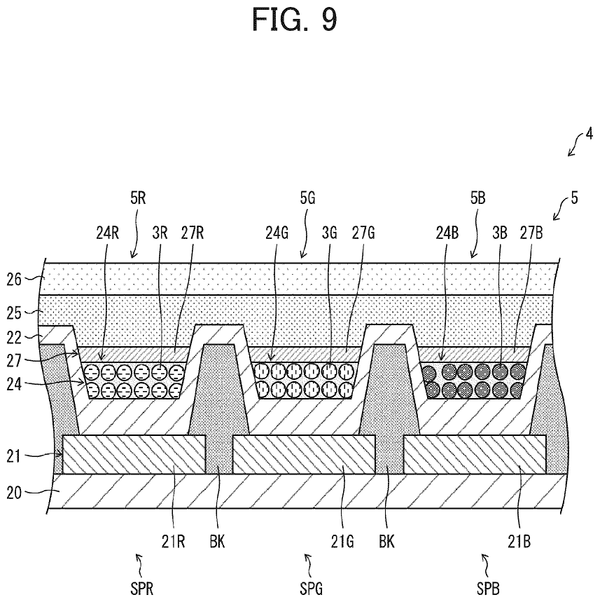

A description is now given to a display device 4 in accordance with the present embodiment with reference to FIG. 9. FIG. 9 is a schematic cross-sectional side view of the display device 4 in accordance with the present embodiment and shows a cross-section that corresponds to the cross-section of the display device 1 shown in FIG. 1. The display device 4 in accordance with the present embodiment, when compared with the display device 1 in accordance with the preceding embodiment, includes light-emitting elements 5 in place of the light-emitting elements 2. The light-emitting elements 5 include a red light-emitting element 5R positioned in the red subpixel SPR, a green light-emitting element 5G positioned in the green subpixel SPG, and a blue light-emitting element 5B positioned in the blue subpixel SPB.

The light-emitting elements 5 have the same structure as the light-emitting elements 2, except that the light-emitting elements 5 include an intermediate layer 27 as a first intermediate layer in place of the intermediate layer 23. The intermediate layer 27 has the same structure as the intermediate layer 23, except that the intermediate layer 27 is provided between the light-emitting layer 24 and the electron transport layer 25 and is in contact with the top face of the light-emitting layer 24 that faces the cathode 26. In other words, the intermediate layer 27 contains a novolac-type phenol resin.

The intermediate layer 27 includes an intermediate layer 27R positioned in the red subpixel SPR, an intermediate layer 27G positioned in the green subpixel SPG, and an intermediate layer 27B positioned in the blue subpixel SPB. Therefore, the red light-emitting element 5R includes the intermediate layer 27R, the green light-emitting element 5G includes the intermediate layer 27G, and the blue light-emitting element 5B includes the intermediate layer 27B.

The light-emitting elements 5 in accordance with the present embodiment may be manufactured by a method in which the method of manufacturing the light-emitting elements 2 in accordance with the preceding embodiment is partially altered. For example, in the method of manufacturing the light-emitting elements 5, the substrate 20, the anode 21, the bank BK, and the hole transport layer 22 may be formed by the same method as steps S1 to S4 illustrated in FIG. 3.

In the present embodiment, the light-emitting layer 24 may be formed subsequent to the formation of the hole transport layer 22. The light-emitting layer 24, in the present embodiment, may be formed by the same method as steps S5 to S11 described above, except that the first coating film 42 exposed to light in step S8 is completely removed. Therefore, the light-emitting layer 24 in accordance with the present embodiment may have a superlattice structure of quantum dots.

It should be understood however that in this method, the first coating film 41 may not contain a novolac-type phenol resin, and no superlattice structure of quantum dots may be provided in step S10. Therefore, the light-emitting layer 24 in accordance with the present embodiment may not have a superlattice structure of quantum dots. Alternatively, the light-emitting layer 24 may be formed by selectively applying a material by, for example, inkjet technology.

In the present embodiment, the intermediate layer 27 may be formed subsequent to the formation of the light-emitting layer 24. In the step of forming the intermediate layer 27, for example, first, the above-described first solution is applied onto the light-emitting layer 24 and the bank BK to form the first coating film 41. Next, only the first coating film 41 that overlaps the light-emitting layer 24 in a plan view of the substrate 20 is exposed to light by using a photomask, to start condensation polymerization of a phenolic compound. The first coating film 42 containing a novolac-type phenol resin is hence formed only on the light-emitting layer 24. Next, the unexposed first coating film 41 is rinsed off in a suitable development solution so that the residual exposed, first coating film 42 becomes the intermediate layer 27.

After the formation of the intermediate layer 27, in the present embodiment, the electron transport layer 25 and the cathode 26 may be formed by the same method as step S12 and step S13 described above.

In the present embodiment, the intermediate layer 27 again contains a novolac-type phenol resin that tends to be polymerized with the hydroxy groups in the phenol being aligned in condensation polymerization. Therefore, in the present embodiment, the planarity of the face of the intermediate layer 27 that is in contact with the light-emitting layer 24 also improves, which improves the closeness of the intermediate layer 27 and the light-emitting layer 24. Therefore, the luminous efficiency of the light-emitting elements 5 is improved by the reduction of the local luminescence of the light-emitting layer 24 caused by the local contact of the intermediate layer 27 with the light-emitting layer 24.

The light-emitting elements 5 include the intermediate layer 27 between the cathode 26 and the light-emitting layer 24. Therefore, the light-emitting elements 5 are capable of improving the efficiency of electron injection to the light-emitting layer 24 by improving adherence between the intermediate layer 27 and the light-emitting layer 24. The light-emitting elements could be excessively rich in holes where the concentration of the holes injected to the light-emitting layer is lower than the concentration of the electrons injected to the light-emitting layer, depending on the design of each layer. When this is the case, the light-emitting elements 5 reduce the excessive richness in holes of the light-emitting layer 24 by improving the efficiency of electron injection to the light-emitting layer 24, thereby improving the charge-carrier balance in the light-emitting layer 24. Therefore, the light-emitting elements 5 more efficiently improve the luminous efficiency and furthermore reduce the progress of the degradation of the light-emitting layer 24, thereby extending the lifespan.

In addition, the light-emitting elements 5 include the electron transport layer 25 between the cathode 26 and the intermediate layer 27. The light-emitting elements 5 are capable of improving adherence between the intermediate layer 27 and the light-emitting layer 24 regardless of the planarity of the bottom face of the electron transport layer 25 that faces the light-emitting layer 24. Therefore, the light-emitting elements 5 are capable of improving adherence between the intermediate layer 27 and the light-emitting layer 24 regardless of, for example, the material(s) contained in the electron transport layer 25 and the method of forming the electron transport layer 25. For example, the electron transport layer 25 contains, for example, nanoparticles of nickel oxide (NiO) as an electron-transportable material. In such cases, the light-emitting elements 5 can likewise capable of improving adherence between the intermediate layer 27 and the light-emitting layer 24. Therefore, the light-emitting elements 5 achieve both freedom in the material of the electron transport layer 25 and in the method of manufacturing the electron transport layer 25 and improvement of the luminous efficiency.

### Embodiment 3

### Second Intermediate Layer

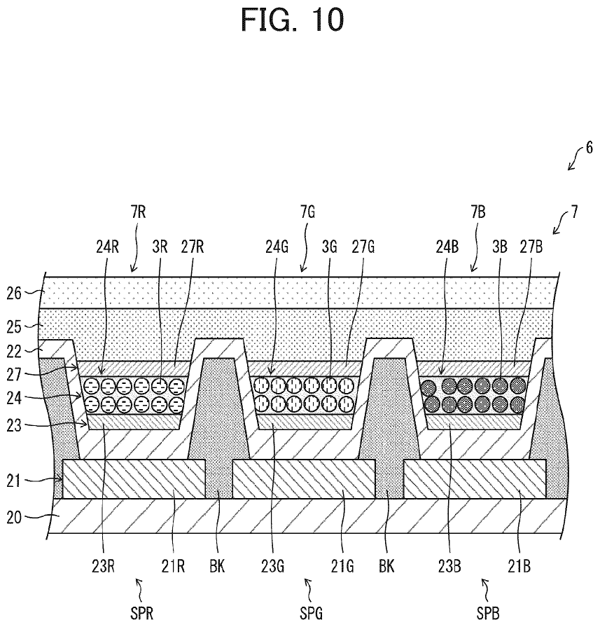

A description is now given of a display device 6 in accordance with the present embodiment with reference to FIG. 10. FIG. 10 is a schematic cross-sectional side view of the display device 6 in accordance with the present embodiment and shows a cross-section that corresponds to the cross-section of the display device 1 shown in FIG. 1. The display device 6 in accordance with the present embodiment, when compared with the display device 1 or the display device 4 in accordance with the foregoing embodiments, includes light-emitting elements 7 in place of the light-emitting elements 2 or the light-emitting elements 5. The light-emitting elements 7 include a red light-emitting element 7R positioned in the red subpixel SPR, a green light-emitting element 7G positioned in the green subpixel SPG, and a blue light-emitting element 7B positioned in the blue subpixel SPB.

The light-emitting elements 7 have the same structure as the light-emitting elements 2 or the light-emitting elements 5, except that the light-emitting elements 7 include both the intermediate layer 23 as a first intermediate layer and the intermediate layer 27 as a second intermediate layer. In other words, the light-emitting elements 7 include both the intermediate layer 23 that is in contact with the bottom face of the light-emitting layer 24 that faces the anode 21 and the intermediate layer 27 that is in contact with the top face of the light-emitting layer 24 that faces the cathode 26, and the intermediate layer 23 and the intermediate layer 27 contain a novolac-type phenol resin. The red light-emitting element 7R includes the intermediate layer 23R and the intermediate layer 27R, the green light-emitting element 7G includes the intermediate layer 23G and the intermediate layer 27G, and the blue light-emitting element 7B includes the intermediate layer 23B and the intermediate layer 27B.

The light-emitting elements 7 in accordance with the present embodiment may be manufactured by a method in which the method of manufacturing the light-emitting elements 2 or the light-emitting elements 5 in accordance with the aforementioned embodiments is partially altered. For example, in the method of manufacturing the light-emitting elements 7, the substrate 20, the anode 21, the bank BK, the hole transport layer 22, the intermediate layer 23, and the light-emitting layer 24 may be formed by the same method as steps S1 to S11 illustrated in FIG. 3. Therefore, in the present embodiment, any light-emitting layer 24 may have a superlattice structure of quantum dots. In the present embodiment, subsequent to the formation of the light-emitting layer 24, the intermediate layer 27 may be formed by the same method as the method of forming the intermediate layer 27 in accordance with the preceding embodiment. After the formation of the intermediate layer 27, in the present embodiment, the electron transport layer 25 and the cathode 26 may be formed by the same method as steps S12 and S13 described above.

In the present embodiment, both the planarity of the surface of the intermediate layer 23 that is in contact with the light-emitting layer 24 and the planarity of the surface of the intermediate layer 27 that is in contact with the light-emitting layer 24 are improved, which improves both the closeness of the intermediate layer 23 and the light-emitting layer 24 and the closeness of the intermediate layer 27 and the light-emitting layer 24. Therefore, the light-emitting elements 7 reduce both the local contact of the intermediate layer 23 with the light-emitting layer 24 and the local contact of the intermediate layer 27 with the light-emitting layer 24, which further improves luminous efficiency. In addition, the light-emitting elements 7 improve both the efficiency of the injection of holes to the light-emitting layer 24 and the efficiency of the injection of electrons to the light-emitting layer 24 by including both the intermediate layer 23 and the intermediate layer 27, which further improves luminous efficiency.

The disclosure is not limited to the description of the embodiments above and may be altered within the scope of the claims. Embodiments based on a proper combination of technical means disclosed in different embodiments are encompassed in the technical scope of the disclosure. Furthermore, new technical features can be created by combining different technical means disclosed in the embodiments.

1. A light-emitting element comprising:
a first electrode;
a second electrode;
a light-emitting layer positioned between the first electrode and the second electrode; and
a first intermediate layer positioned in contact with the light-emitting layer either between the first electrode and the light-emitting layer or between the second electrode and the light-emitting layer or both between the first electrode and the light-emitting layer and between the second electrode and the light-emitting layer, wherein
the first intermediate layer contains a novolac-type phenol resin.

2. The light-emitting element according to claim 1, wherein the light-emitting layer contains a plurality of quantum dots.

3. The light-emitting element according to claim 2, wherein the light-emitting layer contains ligands capable of being coordinated to the quantum dots.

4. The light-emitting element according to claim 1 further comprising a substrate, wherein the first electrode, the first intermediate layer, the light-emitting layer, and the second electrode are provided sequentially on the substrate when viewed from the substrate.

5. The light-emitting element according to claim 1, wherein the novolac-type phenol resin has a general formula of 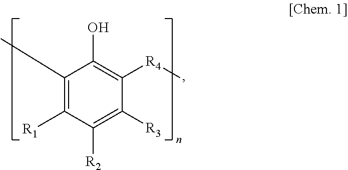
where n is an integer of from 1 to 4 both inclusive, each of R₁, R₂, and R₃ is a H or a C₁-C₄ alkyl group with or without a substituent, and R₄ is a C₁-C₃ aliphatic compound with or without a substituent.

6. The light-emitting element according to claim 1, wherein the first intermediate layer has a thickness of from 5 nm to 20 nm both inclusive.

7. The light-emitting element according to claim 1, wherein the first intermediate layer contains a photosensitive resin.

8. The light-emitting element according to claim 1, wherein
the first electrode is an anode, and
the second electrode is a cathode.

9. The light-emitting element according to claim 8, wherein the first intermediate layer is provided between the anode and the light-emitting layer.

10. The light-emitting element according to claim 9 further comprising a hole transport layer positioned between the anode and the first intermediate layer.

11. The light-emitting element according to claim 8, wherein the first intermediate layer is provided between the cathode and the light-emitting layer.

12. The light-emitting element according to claim 11 further comprising an electron transport layer positioned between the cathode and the first intermediate layer.

13. The light-emitting element according to claim 1, wherein
the first intermediate layer is provided between the first electrode and the light-emitting layer,
the light-emitting element further comprises a second intermediate layer positioned in contact with the light-emitting layer between the second electrode and the light-emitting layer, and
the second intermediate layer contains the novolac-type phenol resin.

14. A display device comprising a light-emitting element according to claim 1.

15. A method of manufacturing a light-emitting element including: a first electrode; a second electrode; a light-emitting layer positioned between the first electrode and the second electrode; and a first intermediate layer positioned in contact with the light-emitting layer either between the first electrode and the light-emitting layer or between the second electrode and the light-emitting layer or both between the first electrode and the light-emitting layer and between the second electrode and the light-emitting layer, the method comprising:
forming a first coating film by applying a first solution containing a phenolic compound; and
forming the first intermediate layer containing a novolac-type phenol resin by condensation polymerization of the phenolic compound in at least a part of the first coating film.

16. The method of manufacturing a light-emitting element according to claim 15 further comprising:
applying a second solution containing a plurality of quantum dots to sites including on the first intermediate layer; and
forming a second coating film containing the plurality of quantum dots by drying the applied second solution, wherein
a part of the second coating film that overlaps the first intermediate layer in a plan view is at least a part of the light-emitting layer.

17. The method of manufacturing a light-emitting element according to claim 16, wherein
the first coating film contains a photosensitive resin,
in forming the first intermediate layer, the condensation polymerization of the phenolic compound in at least a part of the first coating film starts when the first coating film is at least partly exposed to light, and
the forming of the first intermediate layer includes removing a part of the first coating film that has been exposed to light, by rinsing the first coating film using a development solution.

18. The method of manufacturing a light-emitting element according to claim 17, wherein the applying of the second solution includes applying the second solution onto the first intermediate layer and onto the unexposed first coating film.

19. The method of manufacturing a light-emitting element according to claim 18 further comprising removing at least a part of the unexposed first coating film and removing the second coating film on the unexposed first coating film, by rinsing the first coating film and the second coating film using a rinsing liquid.
